(19) United States
(12) Patent Application Publication
(10) Pub. No.: US 2024/0112904 A1
(43) Pub. Date: Apr. 4, 2024

(54) PLASMA PROCESS UNIFORMITY BY WAFER BACK SIDE DOPING

(71) Applicant: SKYWORKS GLOBAL PTE. LTD., Singapore (SG)

(72) Inventors: Kezia Cheng, Lowell, MA (US); Kwang Jae Shin, Yongin (KR); Taecheol Shon, Hwaseong (KR); Yong Woo Jeon, Anseong (KR); Alan Sangone Chen, Leesburg, FL (US)

(21) Appl. No.: 18/370,452

(22) Filed: Sep. 20, 2023

Related U.S. Application Data
(60) Provisional application No. 63/411,778, filed on Sep. 30, 2022.

(51) Int. Cl. H01L 21/02; H01L 21/687

(52) U.S. Cl. CPC H01L 21/02274; H01L 21/02293; H01L 21/02359; H01L 21/68714

(57) ABSTRACT

Disclosed are systems and methods for improving front-side process uniformity by back-side doping. In some implementations, a highly conductive doped layer can be formed on the back side of a semiconductor wafer prior to certain process steps such as plasma-based processes. Presence of such a back-side doped layer reduces variations in, for example, thickness of a deposited and/or etched layer resulting from the plasma-based processes. Such reduction in thickness variations can result from reduced variation in radio-frequency (RF) coupling during the plasma-based processes.

### CROSS-REFERENCE TO RELATED APPLICATIONS

This application claims priority under 35 U.S.C. § 119(e) to U.S. Provisional Patent Application Ser. No. 63/411,778, titled “PLASMA PROCESS UNIFORMITY BY WAFER BACK SIDE DOPING,” filed Sep. 30, 2022, the entire content of which is incorporated herein by reference in its entirety for all purposes.

### BACKGROUND

### Technical Field

The present disclosure generally relates to methods and systems for processing semiconductor wafers.

### Description of Related Technology

Semiconductor devices are commonly implemented on a semiconductor wafer and separated into individual devices. Formation of such devices typically includes processing of the wafer utilizing various process steps. Such process steps typically include deposition of materials, as well as removal of materials in some selected manners, to form desired features on the wafer.

In some implementations, such deposition and removal of materials can be achieved by techniques such as plasma-based processes. A plasma-enhanced chemical vapor deposition (PECVD) process is an example of such a plasma-based deposition process. A reactive ion etching process is an example of such a plasma-based removal process.

### SUMMARY

In accordance with one aspect, there is provided a method for processing a semiconductor wafer. The method comprises providing a high resistivity wafer having a back side and a front side, doping one side of the high resistivity wafer to form a doped layer having an increased conductivity on the one side of the high resistivity wafer, and performing a plasma-based process on the other side of the high resistivity wafer, the doped layer affecting at least one of an etch rate and a deposition rate during the plasma-based process so as to facilitate improved uniformity in thickness of a layer resulting from the plasma-based process.

In some embodiments, the doped layer is formed on the back side of the high resistivity wafer and the plasma-based process is performed on the front side of the high resistivity wafer.

In some embodiments, the doped layer covers substantially the entire area of the back side of the high resistivity wafer.

In some embodiments, the doped layer is formed using a diffusion process.

In some embodiments, the doped layer is formed using an ion implantation process.

In some embodiments, the doped layer is formed using an epitaxial deposition process.

In some embodiments, the plasma-based process includes a deposition process.

In some embodiments, the deposition process includes a plasma-enhanced chemical vapor deposition (PECVD) process.

In some embodiments, the plasma-based process includes an etching process.

In some embodiments, the etching process includes a reactive ion etching process.

In some embodiments, the layer resulting from the plasma-based process includes a nitride layer.

In some embodiments, the improved uniformity includes a reduction in relative standard deviation of measured thickness values by a factor of at least two when compared to similar thickness values corresponding to a high resistivity wafer without a doped layer on its back side.

In some embodiments, providing the high resistivity wafer includes providing one of a silicon or a gallium arsenide wafer.

In some embodiments, the method further comprises removing the doped layer after performing the plasma-based process.

In accordance with another aspect, there is provided a method for processing a high resistivity semiconductor wafer. The method comprises providing the high resistivity semiconductor wafer, and doping on one side of the high resistivity semiconductor wafer to form a doped layer on the one side of the high resistivity semiconductor wafer to reduce variation in radio-frequency (RF) coupling during a plasma-based process on the other side of the high resistivity semiconductor wafer, the reduced variation in RF coupling facilitating improved uniformity in at least one of an etch rate and a deposition rate during the plasma-based process.

In some embodiments, the method further comprises performing the plasma-based process on the other side of the high resistivity semiconductor wafer.

In some embodiments, the method further comprises removing the doped layer after the plasma-based process.

In some embodiments, the variation in RF coupling includes a contribution from one or more features defined by or associated with a wafer handling device.

In some embodiments, the wafer handling device includes a wafer platen.

In some embodiments, the wafer handling device includes a wafer chuck.

In accordance with another aspect, there is provided a method to process a high resistivity semiconductor wafer. The method comprises providing the high resistivity semiconductor wafer, doping a back side of the high resistivity semiconductor wafer to form a doped layer on the back side of the high resistivity semiconductor wafer, and performing a plasma-based process according to a front-side design on a front side of the high resistivity semiconductor wafer, the doped layer including varying thickness profiles to accommodate the front-side design, the varying thickness profiles of the doped layer affecting at least one of an etch rate and a deposition rate during the plasma-based process.

### BRIEF DESCRIPTION OF THE DRAWINGS

Embodiments of this disclosure will now be described, by way of non-limiting example, with reference to the accompanying drawings.

FIG. 1 schematically shows a fabrication system having one or more features described herein;

FIG. 2 shows that the fabrication system can include a plasma etch apparatus that can yield more uniform results on macro scale of wafers when such wafers have back-side metallization;

FIG. 3 shows an example sequence of back-side metallization and front-side process performed on a wafer to demonstrate improved uniformity provided by the back-side metallization;

FIG. 4 shows an example sequence of front-side process performed on a wafer without the back-side metallization as a reference for comparison with the example of FIG. 3;

FIG. 5 shows a comparison of examples of wafers with and without backside metallization processed as described in U.S. Pat. No. 8,956,979;

FIG. 6 shows a wafer platen of a deposition system utilized for the example wafers of FIG. 5;

FIG. 7 shows a wafer chuck of an etch tool utilized for the example wafers of FIG. 5;

FIG. 8 shows a process that can be implemented to yield a processed wafer having one or more features described herein;

FIG. 9 shows a version of the process of FIG. 8 utilizing diffusion to form a doped layer on a back side of a wafer; and

FIG. 10 shows a version of the process of FIG. 8 utilizing ion implantation to form a doped layer on a back side of a wafer.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Semiconductor processes typically have some inherent non-uniformity. Depending on, for example, mask and technology, the wafer maps can have non-uniform patterns that are radial, along a lateral direction, and/or random. In an example context of a plasma process, effects associated with radio-frequency (RF) coupling can yield such patterns, which in turn can contribute to high variability in device performance or poor device performance, including significant failure rates, and decreased yield.

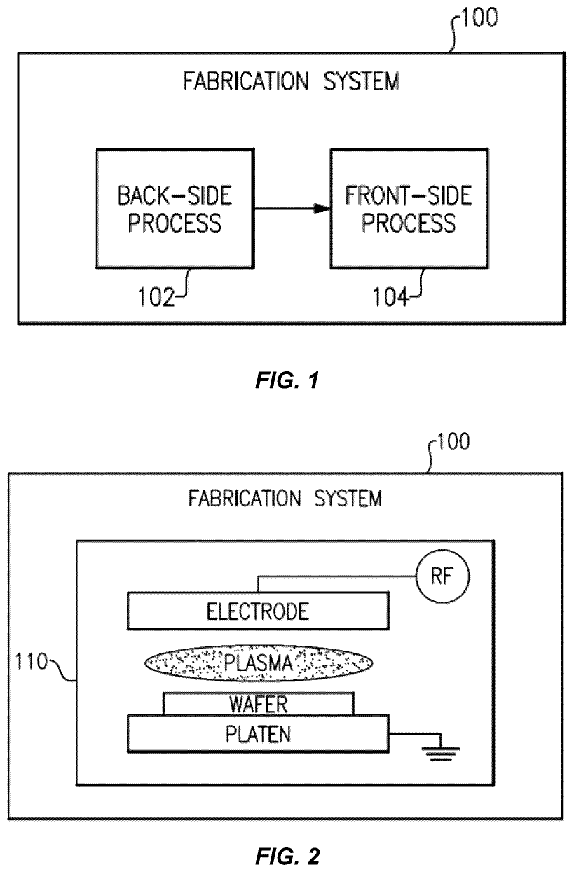

FIG. 1 shows that in some implementations, a semiconductor fabrication system 100 can be configured to include one or more features as described herein. The fabrication system 100 can include a back-side process component 102 and a front-side component 104. In some implementations, the back-side process component 102 can be configured to include a back-side doping process that yields wafers whose back-sides are doped with either n-type or p-type dopants. Such back-side doped wafers can then have their front-sides processed by the front-side process component 104 so as to yield desired devices (such as integrated circuits or MEMS devices such as acoustic wave resonators) on the wafers. For the purpose of description, it will be understood that the back-side process component 102 and the front-side process component 104 can be parts of a single facility, or belong to different facilities.

In such fabrication systems, plasma processes can be an integral and important part of semiconductor device fabrication. Applications of such plasma processes can include dry etching of metals, dielectrics, and semiconductors; chemical vapor deposition of thin films; and oxygen plasma descum for organics removal. While each of these example processes can play an important role in the performance of a device being fabricated, process uniformity across a given wafer can also be important for consistent probe yield. If a plasma process condition varies drastically on the wafer (e.g., from the center of the wafer to the edge), device performance can vary at different locations on the wafer, and probe yield can be affected.

Some parameters that are important in a plasma process can include temperature, gas flows, gas chemistries, pressures, and powers. Each of these parameters can modify the etching or deposition process characteristics. As described herein, overall process uniformity can be enhanced by increasing the conductivity of the backside of a wafer by doping via ion implantation, diffusion, or epitaxial deposition of a doped layer. In various embodiments any conventional dopants may be used to dope the back side of a wafer to achieve a desired back-sed conductivity. For silicon wafers these dopants may be, for example, group V elements such as arsenic or phosphorous or group III elements such as boon.

By way of an example, GaAs devices can be fabricated on semi-insulating substrates with bulk resistivities on the order of 10⁸ Ω-cm. Devices such as bulk acoustic wave resonators may be fabricated on silicon substrates, for example, intrinsic silicon substrates having bulk resistivities on the order of 500 kΩ-cm. As the term is used herein a “high-resistivity substrate” may exhibit a bulk resistivity of 100 kΩ-cm or greater. The high resistivity of the substrate can inhibit efficient coupling of RF power during a plasma process. Such a phenomenon can be more pronounced at the front end of the wafer fabrication process where the metalized area is usually small. Prophetic examples of uniformity comparison with and without the back-side doping are described herein in greater detail. As also described herein, improved uniformity facilitated by the back-side doping can translate into improved test parameters and yield gain.

A uniform wafer map with high yield is a very desirable goal of semiconductor fabrication processes. However, such a desirable goal may not be realized for a number of reasons. Quite often, a wafer map can display a distinctive pattern that is caused by one or a combination of several processes. The micro-loading effect in a plasma etch process can also cause local etch non-uniformity.

Described herein are systems and methodologies for achieving an improved uniformity on a macro scale (e.g., at a wafer level) resulting from processes such as a plasma process. By way of an example, such a plasma process is described in the context of an effect of radio-frequency (RF) coupling on plasma process uniformity.

FIG. 2 schematically depicts a plasma process apparatus 110 that can be a part of the fabrication system 100. In some implementations, such an apparatus can be a reactive ion etch (RIE) apparatus or a plasma-enhanced chemical vapor deposition (PECVD) apparatus. In an example of a capacitively coupled plasma reactor with a parallel-plate configuration, RF power is depicted as being applied to one of the electrodes (the upper electrode in the example of FIG. 2) while the other electrode (depicted as a platen in FIG. 2) is depicted as being electrically grounded. A wafer is shown to be positioned on the platen and subjected to plasma due to the applied RF power.

It will be understood that the plasma process apparatus 110 of FIG. 2 can be configured in other ways. For example, RF power can be applied to the platen and the top electrode can be grounded. In another example, both of the electrodes (e.g., top electrode and platen) can be RF biased. Other configurations are also possible.

In the context of gallium arsenide (GaAs) processes, GaAs devices can be built on a semi-insulating substrate with a bulk resistivity on the order of 10⁸ Ω-cm. When a GaAs wafer having such a high resistivity (which may be desirable for device fabrication) is subjected to the RIE system 110, the high resistivity can impede effective RF power coupling. In some situations, such an effect can lead to non-uniform etching or deposition. Similarly, for high resistivity silicon substrates processed in the RIE system 110, the high resistivity can also impede effective RF power coupling and lead to non-uniform etching or deposition.

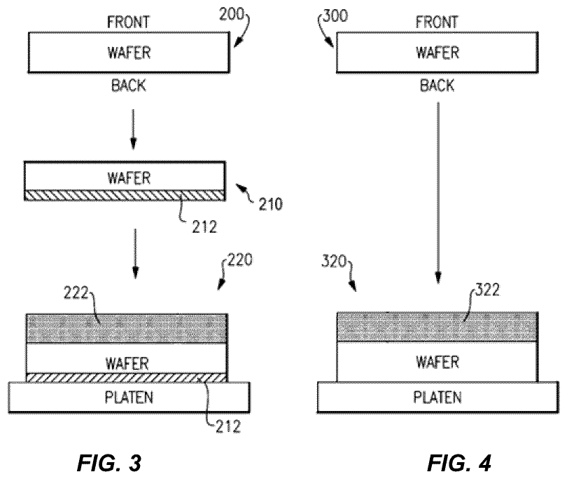

Described herein is an example of how back-side doping of a semiconductor wafer can result in improved RF power coupling during a plasma process so as to yield improved uniformity in etching or deposition. To demonstrate such an improvement, a number of silicon wafers with different back-side doping levels and different resistivities were used in an experiment. FIG. 3 shows various stages of plasma processing of a back-side doped wafer 200, 210, and FIG. 4 shows various stages of plasma processing of a wafer 300 that does not have back-side doping.

To obtain wafers for testing, several silicon wafers were recovered from reclaim and their back side resistivities were measured. In FIG. 3, the resulting back-side doped configuration 210 is depicted as a layer of doped silicon 212 being formed on the back-side of the wafer 200. In some embodiments, the doped layer 212 can have a thickness in a range of 10 angstroms to 5 microns, 100 angstroms to 1 micron, 200 angstroms to 5,000 angstroms, 400 angstroms to 3,000 angstroms, 500 angstroms to 2,000 angstroms, 600 angstroms to 1,500 angstroms, 700 angstroms to 1,300 angstroms, 800 angstroms to 1,200 angstroms, or 900 angstroms to 1,100 angstroms.

The different silicon wafers then received deposition of approximately 1,000 angstroms of compressive silicon nitride film in a Novellus PECVD (plasma-enhanced chemical vapor deposition) apparatus. In FIG. 3, configuration 220 shows a nitride layer 222 formed on the front side of the wafer. In FIG. 4, configuration 320 shows a nitride layer 322 formed on the front side of the wafer.

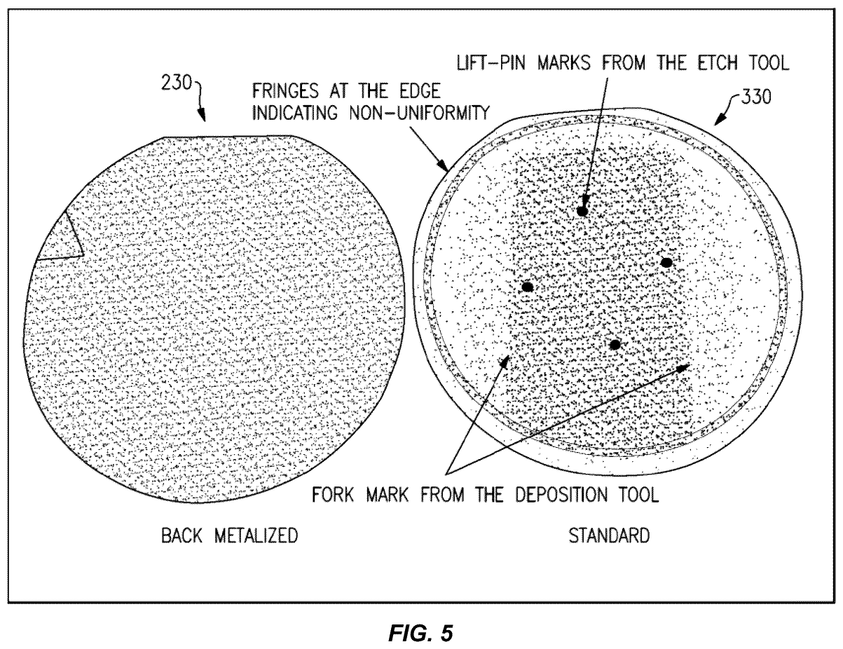

Previous experiments were performed test the effect of back-side metallization on GaAs wafers subjected to plasma deposition and etch operations. These experiments are described in U.S. Pat. No. 8,956,979 (the '979 Patent), incorporated herein by reference. FIG. 5 of the '979 Patent is reproduced herein and shows a comparison of a back-side metalized (BSM) wafer 230 (indicated as “BACK METALIZED”) and a non-BSM wafer 330 (indicated as “STANDARD”) resulting from the experiment described in the '979 Patent. It can be seen that the two wafers appear markedly different. The BSM wafer has a generally uniform shade across substantially the entire surface indicating generally uniform thickness. The non-BSM wafer shows fringes at the edge (e.g., a first band about 14 mm wide on the edge, and a second thinner ring inside the first band) indicating non-uniformity in thickness. Further, the non-BSM wafer shows a broad stripe about 2 inch wide down the middle of the wafer. It is believed that boundaries of such a stripe correspond to imprints of the wafer handler of the nitride deposition apparatus. Further, the center portion of the non-BSM wafer has four dots, which are believed to correspond to marks left by the lift-pins on the chuck of the etch apparatus.

In experiments performed by plasma deposition of silicon nitride on silicon wafers with different back-side conductivities, it was observed that silicon wafers with a back side conductivity of about 300Ω/sq appeared similar to the BSM GaAs wafer 230 of FIG. 5, while silicon wafers with lower back-side conductivities exhibited a stripe of different nitride thickness similar to that of the non-BSM wafer 330 of FIG. 5.

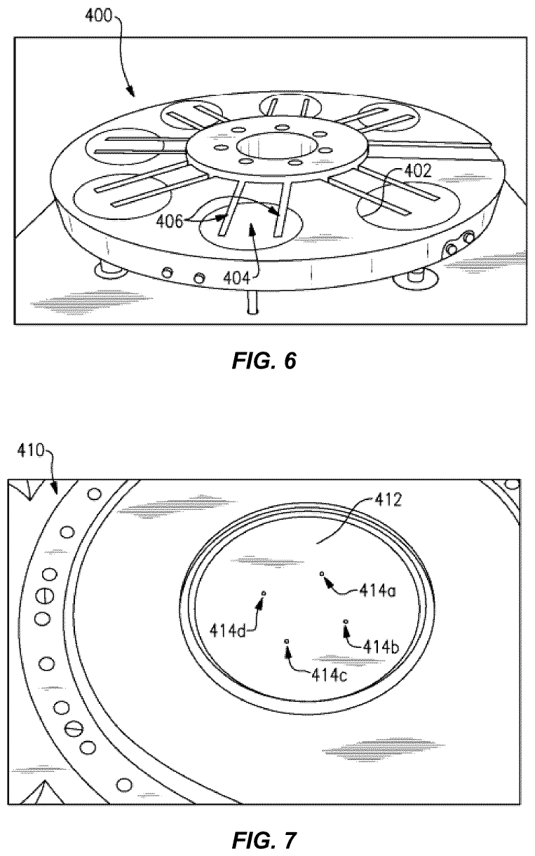

Some of the example undesirable features shown in the non-BSM wafer 330 of FIG. can be explained by considering the example deposition system 400 shown in FIG. 6. In the example system (e.g., Novellus PECVD system), a wafer platen 402 is shown to include a plurality of recesses 404 for receiving wafers. Positioning and lifting of wafers into and out of the recesses 404 can be accommodated by fork shaped wafer handlers 406. In the non-BSM wafer 330 of FIG. 5, the 2 inch stripe generally corresponds to an area between the two prongs of the fork.

It is noted that in the example non-BSM wafer 330 of FIG. 5, the silicon nitride outside of the fork region transitioned to a different color. Reflectometry measurement indicated that the silicon nitride in this region was about 200 to 500 angstroms thinner compared to the region of the wafer inside the fork. Thus, one can see that the wafer handler can have undesirable impact on a wafer's thickness uniformity.

FIG. 7 shows a wafer chuck 410 of an etch tool. The chuck 410 is shown to define a wafer-receiving area 412. Within the wafer-receiving area 412 are shown four lift-pins 414a-414d that facilitate positioning and removal of a wafer. Each of such pins has a diameter of approximately 3 mm.

The example non-BSM wafer 330 of FIG. 5 shows a pattern of four dots that correspond to the four lift-pins. The dots on the non-BSM wafer were measured to have a thickness of about 4565 angstroms. In comparison, neighboring areas outside the fork region have an average thickness of about 4362 angstroms. Thus, one can see that the pin pattern of the RIE chuck contributes to a nitride thickness variation of about 200 angstroms. It is believed that the four holes (machined in the chuck) for allowing retractions of the four lift-pins can yield a change in capacitance and therefore lessen RF coupling. Lower etch rate therefore resulted on the front of the wafer in the corresponding locations.

Similar pin patterns may appear in the silicon nitride layers formed by plasma deposition and etching on high resistivity silicon wafers. It is expected that by doping the back sides of such high resistivity silicon wafers such that they exhibit a sufficiently high conductance, such pin patterns may be minimized or eliminated.

A cavity in the wafer chuck such as a lift-pin hole or wafer-handler recess in the platen can alter the capacitive and/or RF power coupling effectiveness and thereby affect the etch and/or deposition rates. In a semiconductor device where a dimension is important for device performance, this amount of variation can cause performance difference and yield loss. For example, if there is insufficient over-etch built-in in an etch recipe, areas with very low etch rates would have a smaller dimension and run a risk of incomplete etch. At the same time, areas with high etch rates may experience an enlarged dimension and even surface damage.

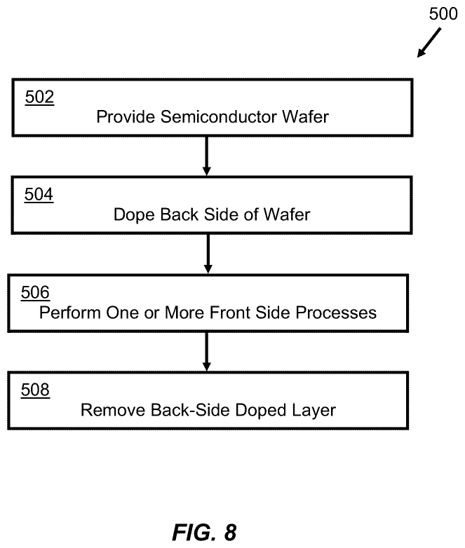

FIG. 8 shows a process 500 that can be implemented to achieve desirable results associated with a back-side doped wafer. In block 502, a semiconductor wafer can be provided or formed. In block 504, one side (e.g., back side) of the wafer can be doped utilizing, for example, ion implantation, diffusion, or epitaxial growth so as to form a doped layer. In some implementations, such doping can yield a doped layer that covers substantially the entire surface of the back side. In block 506, one or more front-side processes can be performed on the back-side doped wafer. In block 508 the back-side doped layer may be removed, for example, by CMP, grinding, or etching.

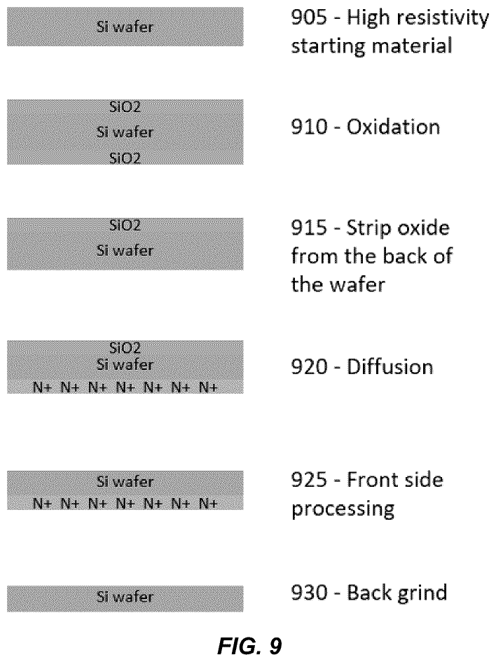

FIG. 9 illustrates steps in a version of the process of FIG. 8 where the back-side-doped layer is provided by diffusion. In act 905 a high resistivity semiconductor wafer or substrate may be provided. A silicon wafer is illustrated, but this could be GaAs or any other type of semiconductor wafer or substrate with a high resistivity. In act 910 the front and rear surfaces are oxidized, for example, in a diffusion furnace. Alternatively, layers of oxide or other dielectric may be deposited on the front and back of the wafer by chemical vapor deposition or physical deposition (sputtering or evaporative deposition). In act 915 the oxide layer is stripped from the back of the wafer, for example, by polishing, grinding, and/or etching. In act 920 dopants are diffused into the back side of the wafer to form a doped back side layer using, for example, a diffusion furnace. N-type dopants are illustrated, but the dopants could alternatively be p-type. A sufficient amount of dopants are diffused into the back side of the wafer to provide the back side with sufficiently low resistivity to mitigate non-uniformity effects in plasma processing equipment to a desired degree. In act 925, front-side processing, for example, the formation of transistors, MEMS devices (e.g., acoustic wave resonators), and/or other circuitry is performed. After front-side processing is complete, the doped back-side layer is removed in act 930, for example, by polishing, grinding, and/or etching.

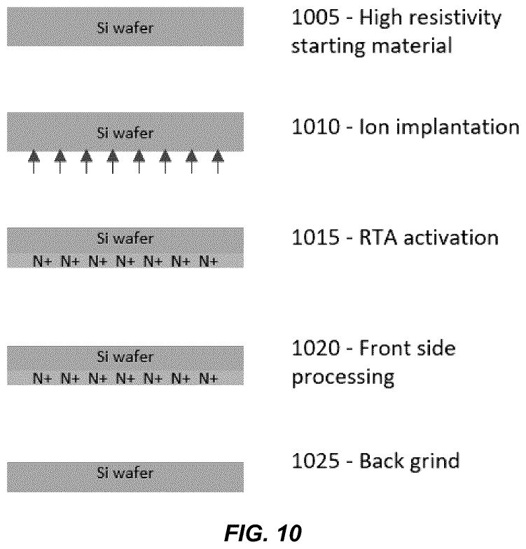

FIG. 10 illustrates steps in a version of the process of FIG. 8 where the doped back-side layer is provided by ion implantation. In act 1005 a high resistivity semiconductor wafer or substrate may be provided. A silicon wafer is illustrated, but this could be GaAs or any other type of semiconductor wafer or substrate with a high resistivity. In act 1010 dopants are implanted into the back side of the wafer by ion implantation. A sufficient dosage of dopants may be ion implanted to provide the back side with sufficiently low resistivity to mitigate non-uniformity effects in plasma processing equipment to a desired degree. In act 1015, the dopants are activated, for example, by a rapid thermal anneal (RTA) process. N-type dopants are illustrated, but the dopants could alternatively be p-type. In act 1020, front-side processing, for example, the formation of transistors, MEMS devices (e.g., acoustic wave resonators), and/or other circuitry is performed. After front-side processing is complete, the doped back-side layer is removed in act 1025, for example, by polishing, grinding, and/or etching.

The present disclosure demonstrates that, among others, plasma process uniformity in a parallel plate configuration (capacitively coupled plasma reactor) can have intrinsically poor uniformity for a GaAs wafer or a high resistivity silicon wafer. The high resistivity of the semi-insulating substrate can inhibit efficient RF power coupling.

A smooth uninterrupted wafer chuck can be desirable for process uniformity consideration. However, such a design may not be practical since the wafer typically needs to be picked up from the back side. Accordingly, wafer chucks typically have features (such as cavities) to accommodate handling of wafers. Such cavities that facilitate these wafer-handling features can disrupt the capacitive and/or RF power coupling. As described herein, a wafer map can be impacted significantly by such wafer-chuck pattern(s). This phenomenon can be more pronounced in the front end of the process where metallization area is small. Plasma processes towards the back end of the production flow can be less pronounced (sensitive) due to the larger front side metallization area.

In the context of high resistivity silicon wafers or other forms of high resistivity semiconductor wafers or substrates, a doped layer formed on the back side wafer may greatly improve both the nitride deposition and plasma-etch uniformity. Imprint from the wafer handler and the color bands on the edge of the wafer that are normally present may be substantially eliminated or reduced. The improved uniformity may translate into yield gains on masks that are sensitive to dimension (e.g., critical dimension) variation in structures such as acoustic wave resonator structures.

In some implementations, one or more features of the present disclosure can be implemented in other process configurations. For example, tool configurations such as a high density inductively coupled plasma (ICP) etch tool and an electro-static chuck may respond similarly to back-side doping. In addition, effectiveness of front-side metallization may be configured appropriately to aid coupling.

Applicant has demonstrated that back-side doping of a wafer can improve front-side process uniformity. Such a demonstration is described in the context of improved plasma process uniformity. It will be understood, however, that other front-side processes can also benefit from the back-side doping technique. As applied to plasma processes, such improved plasma uniformity on a production mask can result in increased probe yield. For example, nitride deposition and nitride etch processes can yield significantly improved uniform results with back-side doping. Other deposition and/or etch processes associated with plasma process (and/or other front-side processes) can also benefit from back-side doping.

In some embodiments, back-side doping layers may be segmented and/or have varying thickness profiles (e.g., by appropriate masking) to accommodate particular front-side designs. For example, there may be front-side deposition and/or etching related effects that depend on radial position or particular features associated with equipments; and such position-dependence can be addressed by appropriately configured back-side doped layers.

The examples of back-side doping are described herein in the context of plasma-related processes. It will be understood, however, that one or more features of the present disclosure can also be implemented in other wafer fabrication processes.

The examples of back-side doping are described herein in the context of GaAs or Si processes. It will be understood, however, that one or more features of the present disclosure can also be implemented in other semiconductor processes.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method for processing a semiconductor wafer, the method comprising:
providing a high resistivity wafer having a back side and a front side;
doping one side of the high resistivity wafer to form a doped layer having an increased conductivity on the one side of the high resistivity wafer; and
performing a plasma-based process on the other side of the high resistivity wafer, the doped layer affecting at least one of an etch rate and a deposition rate during the plasma-based process so as to facilitate improved uniformity in thickness of a layer resulting from the plasma-based process.

2. The method of claim 1 wherein the doped layer is formed on the back side of the high resistivity wafer and the plasma-based process is performed on the front side of the high resistivity wafer.

3. The method of claim 2 wherein the doped layer covers substantially the entire area of the back side of the high resistivity wafer.

4. The method of claim 2 wherein the doped layer is formed using a diffusion process.

5. The method of claim 2 wherein the doped layer is formed using an ion implantation process.

6. The method of claim 2 wherein the doped layer is formed using an epitaxial deposition process.

7. The method of claim 2 wherein the plasma-based process includes a deposition process.

8. The method of claim 7 wherein the deposition process includes a plasma-enhanced chemical vapor deposition (PECVD) process.

9. The method of claim 2 wherein the plasma-based process includes an etching process.

10. The method of claim 2 wherein the layer resulting from the plasma-based process includes a nitride layer.

11. The method of claim 2 wherein the improved uniformity includes a reduction in relative standard deviation of measured thickness values by a factor of at least two when compared to similar thickness values corresponding to a high resistivity wafer without a doped layer on its back side.

12. The method of claim 1 wherein providing the high resistivity wafer includes providing one of a silicon or a gallium arsenide wafer.

13. The method of claim 1 further comprising removing the doped layer after performing the plasma-based process.

14. A method for processing a high resistivity semiconductor wafer, the method comprising:
providing the high resistivity semiconductor wafer; and
doping on one side of the high resistivity semiconductor wafer to form a doped layer on the one side of the high resistivity semiconductor wafer to reduce variation in radio-frequency (RF) coupling during a plasma-based process on the other side of the high resistivity semiconductor wafer, the reduced variation in RF coupling facilitating improved uniformity in at least one of an etch rate and a deposition rate during the plasma-based process.

15. The method of claim 14 further comprising performing the plasma-based process on the other side of the high resistivity semiconductor wafer.

16. The method of claim 14 further comprising removing the doped layer after the plasma-based process.

17. The method of claim 14 wherein the variation in RF coupling includes a contribution from one or more features defined by or associated with a wafer handling device.

18. The method of claim 17 wherein the wafer handling device includes a wafer platen.

19. The method of claim 17 wherein the wafer handling device includes a wafer chuck.

20. A method to process a high resistivity semiconductor wafer, the method comprising:
providing the high resistivity semiconductor wafer;
doping a back side of the high resistivity semiconductor wafer to form a doped layer on the back side of the high resistivity semiconductor wafer; and
performing a plasma-based process according to a front-side design on a front side of the high resistivity semiconductor wafer, the doped layer including varying thickness profiles to accommodate the front-side design, the varying thickness profiles of the doped layer affecting at least one of an etch rate and a deposition rate during the plasma-based process.
